(19) United States
(12) Patent Application Publication
(10) Pub. No.: US 2006/0183394 A1
(43) Pub. Date: Aug. 17, 2006

(54) ORGANIC LIGHT EMITTING DISPLAY (OLED) AND METHOD OF FABRICATING THE SAME

(76) Inventors: Jae-Jung Kim, Gyeonggi-do (KR); Joon-Young Park, Gyeonggi-do (KR); Jeon-Yeol Lee, Gyeonggi-do (KR); Kyoung-Wook Min, Gyeonggi-do (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/339,898

(22) Filed: Jan. 25, 2006

(30) Foreign Application Priority Data
Feb. 7, 2005 (KR) 10-2005-0011407

(51) Int. Cl. H01J 9/24; H01J 9/00

(52) U.S. Cl. 445/24; 313/504

(57) ABSTRACT

Abstract of the Disclosure

An organic light emitting diode (OLED) display for improving surface characteristics of an indium-tin-oxide (ITO) layer for use as a pixel electrode by performing a surface treatment process after forming a pixel separation layer and before depositing an organic layer and a method of fabricating the same. The method of forming an electrode of a flat panel display includes forming an electrode material on a substrate; patterning the electrode material to form an electrode pattern; forming an insulating layer with a deposition thickness on the substrate; etching the insulating layer to expose a portion of the electrode pattern; and performing a surface treatment process under the condition that the insulating layer is etched by a predetermined thickness from the deposition thickness.

### Detailed Description of the Invention

### CROSS-REFERENCE TO RELATED APPLICATIONS

This application claims the benefit of Korean Patent Application No. 10-2005-0011407, filed on February 7, 2005, in the Korean Intellectual Property Office, the disclosure of which is incorporated herein in its entirety by reference.

### BACKGROUND OF THE INVENTION

1. Field of the Invention

The present invention relates to a flat panel display and more particularly, to an organic light emitting diode (OLED) display for improving characteristics of indium-tin-oxide (ITO) for use in a pixel electrode by performing surface treatment after forming a pixel separation layer, but before depositing an organic layer. The present invention also relates to a method of fabricating the same.

2. Description of the Related Art

In general, an active matrix organic light emitting diode display includes a plurality of pixels on a substrate, wherein each pixel includes at least one switching thin film transistor, one drive thin film transistor, a capacitor and an OLED. The OLED includes a lower electrode as a pixel electrode, an upper electrode and an organic layer interposed between the upper and lower electrodes.

In the OLED, the lower electrode comprises an electrode material having a high work function as an anode electrode. ITO is mostly commonly used for the anode electrode because it has a high luminous transparency, a high electrical conductivity and a high infrared reflectivity. The upper electrode comprises an electrode material having a low work function as a cathode electrode.

When a predetermined bias is externally applied to the anode electrode, holes from the anode electrode and electrons from the cathode electrode are injected into a light-emitting layer. The electrons and the holes thus injected then recombine and emit light of predetermined color.

Two of the most important factors required in the OLED are light-emitting efficiency and long lifetime. Light-emitting efficiency irradiated from the light-emitting layer of the OLED depends to a significant degree on the interface characteristics between the anode electrode and the organic layer formed on the anode electrode. The light-emitting efficiency will also influence the lifetime of the device.

Many methods have been employed to improve the light-emitting efficiency of the OLED. One of the methods includes increasing the work function of an ITO layer used in the lower electrode to inject more carriers into the organic light-emitting layer.

One of the methods of increasing the work function of the ITO layer includes performing a surface treatment. Korean Patent Publication No. 2001-0057125 discloses a method of fabricating an OLED by treating the surface of the ITO layer as an anode electrode with SF₆ plasma to improve the interface characteristics between the anode electrode and an organic layer. Japanese Patent Publication No. 2000-133466 discloses a charge injection light-emitting diode fabricated by treating the surface of the ITO layer using oxygen ions or electrons to improve the interface characteristics between an anode electrode and an organic layer.

The conventional method of fabricating an OLED display includes forming a thin film transistor on a substrate, then forming the OLED connected to the thin film transistor. The formation of the OLED comprises forming a pixel electrode, forming a pixel separation layer with an opening that exposes a portion of the pixel electrode, forming an organic layer and forming an upper electrode as a cathode electrode.

In the conventional method, the pixel separation layer is an insulating layer formed on a substrate. The insulating layer is then etched using a photolithography process to expose a portion of the pixel electrode and thereby form an opening. Finally, an organic layer is deposited on the pixel electrode inside the opening.

Organics or particles (including organic material) left on the surface of the substrate after the etching process on the pixel separation layer are moved to the surface of the pixel electrode inside the opening during the transfer of the glass substrate. The movement of particles may also occur during an alignment operation with a mask for depositing an organic layer. If the organic layer is deposited on the pixel electrode with particles attached to its surface, the particles attached to the pixel electrode act as resistors during the device driving and current is concentrated. As a result, defects such as dark spots may occur and problems may occur, including (1) decreasing light-emitting efficiency and (2) decreasing lifetime.

### SUMMARY OF THE INVENTION

The present invention provides an OLED display for improving surface characteristics of a pixel electrode by performing a surface treatment process to remove organic remnants and particles. The surface treatment process occurs after forming a pixel separation layer with an opening that exposes a portion of a pixel electrode before depositing an organic layer. The invention also discloses a method of fabricating the same.

One embodiment of the present invention is a method of forming an electrode of a flat panel display. The method includes: forming an electrode material on a substrate; patterning the electrode material to form an electrode pattern; forming an insulating layer having a deposition thickness on the substrate; etching the insulating layer to expose a portion of the electrode pattern; and performing a surface treatment process under the condition that the insulating layer is etched by a predetermined thickness from the deposition thickness to improve surface characteristics of the electrode pattern.

In one embodiment the surface treatment process may include a plasma treatment process using at least one of Ar, O₂ and N₂ gas. The surface treatment process may be performed under the condition that the insulating layer is etched by a thickness of 100-1000 Å, preferably, a thickness of 200-800 Å, from the deposition thickness.

In one embodiment the surface treatment process may be performed using at least one gas of O₂, Ar and N₂ gas at a flow rate of 10-600 standard cubic centimeters per minute (sccm), a treatment pressure of 5-700 mTorr and an RF power of 50-600 W.

In some embodiments, the electrode pattern is a transparent conductive layer and the insulating layer is an organic insulating layer. The insulating layer may include a planarized layer or a pixel separation layer. Further, the insulating layer may be etched using a photolithography process.

Another embodiment of the present invention is a method of fabricating an OLED display including forming a lower electrode on a substrate; forming an insulating layer having an opening on the lower electrode with a deposition thickness; performing a surface treatment process under the condition that the insulating layer is etched by a predetermined thickness from the deposition thickness; depositing an organic layer on the lower electrode inside the opening; and forming an upper electrode on the substrate.

The insulating layer may be formed by depositing an organic insulating layer and patterned using a photolithography process to form the opening therein.

Another embodiment of the present invention is an OLED display fabricated by the method of fabricating an OLED display. The method comprises forming a lower electrode on a substrate; forming an insulating layer having an opening on the lower electrode and having a deposition thickness; performing a surface treatment process under the condition that the insulating layer is etched by a predetermined thickness from the deposition thickness; depositing an organic layer on the lower electrode inside the opening; and forming an upper electrode on the substrate.

In some embodiments, the OLED display may further include a thin film transistor having a semiconductor layer and a gate and source/drain electrodes formed on the substrate, in which one of the source/drain electrodes is connected to the lower electrode.

### BRIEF DESCRIPTION OF THE DRAWINGS

The above and other features and advantages of the present invention will become more apparent by describing in detail exemplary embodiments thereof with reference to the attached drawings in which like reference numerals refer to similar parts throughout, which are meant to illustrate and not to limit the invention, and in which:

FIG. 1 is a sectional view of an OLED display;

FIGS. 2A through 2D are sectional views illustrating a method of surface-treating an ITO layer for use as a pixel electrode in an OLED display;

FIG. 3A is a graph illustrating the relationship between voltage and brightness of red color in accordance with surface treatment process conditions in an OLED display;

FIG. 3B is a graph illustrating the relationship between brightness and efficiency of red color in accordance with surface treatment process conditions in an OLED display;

FIG. 4A is a graph illustrating the relationship between voltage and brightness of green color in accordance with surface treatment process conditions in an OLED display; and

FIG. 4B is a graph illustrating the relationship between brightness and efficiency of green color in accordance with surface treatment process conditions in an OLED display.

### DETAILED DESCRIPTION OF THE INVENTION

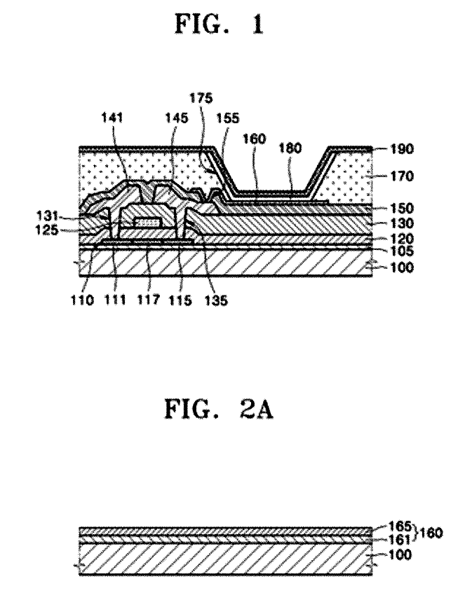

FIG. 1 is a sectional view of an OLED display, according to an embodiment of the present invention, illustrating the OLED device and a thin film transistor for driving the OLED device.

A buffer layer 105 is formed on a substrate 100 and a semiconductor layer 110 is formed on the buffer layer 105. The substrate 100 may be a glass substrate, a plastic substrate or a metal substrate. The semiconductor layer 110 may be a polycrystalline silicon layer.

The semiconductor layer 110 includes source/drain regions 111 and 115 doped with a predetermined conductivity type of impurities such as p-type impurities and a channel region 117, disposed between the source/drain regions 111 and 115, which is not doped with impurities.

A gate insulating layer 120 is formed on the semiconductor layer 110. The gate insulating layer 120 may include a single layer or multiple layers. Further, the gate insulating layer 120 may include an inorganic insulating layer such as a nitride layer or an oxide layer or an organic insulating layer formed of a material, such as polyimide, benzocyclobutene (BCB), parylene, PVP and the like.

A gate 125 is formed on the gate insulating layer 120. An interlayer insulating layer 130 is formed on the gate 125 and the gate insulating layer 120. The interlayer insulating layer 130 may include a single layer, multiple layers, an inorganic insulating layer or an organic insulating layer.

Source/drain electrodes 141 and 145 are formed on the interlayer insulating layer 130 to be connected with the source/drain regions 111 and 115 respectively on the semiconductor layer 110 through contact holes 131 and 135.

A protecting layer 150 is formed on the source/drain electrodes 141 and 145 and the interlayer insulating layer 130. The protecting layer 150 includes a via hole 155 exposing one of the source/drain electrodes 141 and 145. In the embodiment of FIG. 1, the drain electrode 145 is exposed. The protecting layer 150 may include a single layer or multiple layers.

The protecting layer 150 may also include an inorganic insulating layer such as an oxide layer or a nitride layer or an organic insulating layer such as BCB, acryl group of an organic compound, fluoropolyarrylether, cytop, perfluorocyclobutane and the like. Further, the protecting layer 150 may be a stack comprising an organic insulating layer and an inorganic insulating layer.

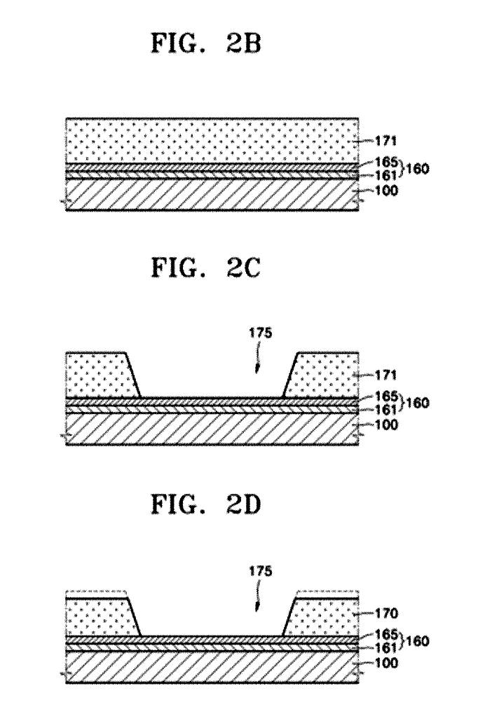

An anode electrode 160 as a lower electrode is formed on the protecting layer 150 to be connected with the drain electrode 145 of the thin film transistor through the via hole 155. Because the OLED display according to this embodiment has a front side light-emitting structure, the anode electrode 160 is a reflective electrode. The anode electrode 160 will be discussed further in reference to FIG. 2.

A pixel separation layer 170 having a thickness of 0.6 (m to 1.2 (m is formed on the anode electrode 160 and the protecting layer 150. The pixel separation layer 170 includes an organic insulating layer such as a polyimide group of an organic layer, an acryl group of an organic layer, BCB or the like. The pixel separation layer 170 also includes an opening 175 exposing a portion of the anode electrode 160.

In one embodiment of the present invention, the pixel separation layer 170 has a thickness reduced by about 100-1000 Å from the thickness of the surface deposition.

An organic layer 180 is formed on the anode electrode 160 inside the opening 175 and a cathode electrode 190 as an upper electrode is formed on the organic layer 180. The cathode electrode 190 comprises a transparent electrode. The organic layer 180 includes one or more organic layers selected from the group consisting of a hole injection layer, a hole transport layer, a light-emitting layer, an electron transport layer, an electron injection layer and a hole blocking layer.

A method of fabricating an OLED display according to the present invention structured as above will be further explained in reference to FIGS. 2A through 2D. In the method of fabricating an OLED display, according to one embodiment of the present invention, fabrication processes before forming an anode electrode as a pixel electrode are the same as processes of a method of fabricating a typical OLED display. A discussion of typical fabrication methods will be omitted here. FIGS. 2A through 2D are thus limited to show a sectional structure of an organic light-emitting device in an OLED display.

In FIG. 2A, a reflecting material having a high reflectance such as AlNd and a transparent conductive material such as ITO are sequentially deposited on the substrate 100 (or on the protecting layer 150 as illustrated in FIG. 1) and are patterned to form an anode electrode 160 composed of a reflective layer 161 and a transparent conductive layer 165.

In other embodiments the anode electrode 160 includes a single transparent electrode composed of a transparent conductive layer 165 and may have a reflective layer 161 in a region of a substrate 100 corresponding to a light emitting region of an organic light emitting layer.

In FIG. 2B, an insulating layer 171 is formed on the anode electrode 160. The insulating layer 171 includes an organic insulating layer such as an acryl group of an organic layer, a polyimide group of an organic layer, BCB or the like.

In FIG. 2C, the insulating layer 171 is patterned, using a photolithography process to form an opening 175 that exposes a portion of the anode electrode 160.

FIG. 2D illustrates that after the opening 175 is formed, a surface treatment process removes remnants of the organic material used as the pixel separation layer 170 or particles. Hence, the pixel separation layer 170 is formed from the insulating layer 171 by removing the organic remnants and particles.

The surface treatment process is performed using plasma and is performed under the condition that the insulating layer 171 is etched by a predetermined thickness, for example, a thickness of 100-1000 Å. The surface treatment process condition of etching the insulating layer 171 by a thickness of 100-1000 Å is as follows:

A mixture of at least one of O₂, Ar and N₂ gas is used. The gas flow may be in a range of 10-600 sccm, the process pressure may be in a range of 5-700 mTorr and the RF power may be in a range of 50-600 W.

In the OLED display of this embodiment, after the opening 175 is formed in the pixel separation layer 170, when the surface treatment process of removing organic remnants and particles has been performed, the pixel separation layer 170 has a thickness reduced by 100-1000 Å from the deposition thickness (dotted line 172 of FIG. 2D).

Table 1 shows a relation between drive voltage and light-emitting efficiency under the surface treatment process conditions of red color. The Process Condition in Table 1 refers to the conditions under which the surface treatment process is performed. Condition A indicates that the pixel separation layer is etched by a thickness less than 100 Å. Condition B indicates that the pixel separation layer is etched by a thickness of 100-1000 Å. Under Condition B the surface treatment process may be performed specifically when the pixel separation layer is etched by a thickness of 800 Å.

TABLE 1

| | Drive | | | Color Coordinates | |
|---|---|---|---|---|---|
| Process | Voltage | Brightness | Efficiency | X | Y |
| Condition | (V) | (Cd/m²⁾ | (Cd/A) | Coordinate | Coordinate |
| Condition | 6.1 | 800 | 4.15 | 0.681 | 0.317 |
| A | | | | | |
| Condition | 5.5 | 800 | 4.90 | 0.680 | 0.319 |
| B | | | | | |

In Table 1, when the pixel separation layer 170 is etched by a thickness less than 100 Å from the deposition thickness to achieve a brightness of 800 Cd/cm², a drive voltage of 6.1 V is required and the light-emitting efficiency is 4.15 Cd/A. In contrast, when the pixel separation layer 170 is etched by a thickness of 100-1000 Å from the deposition thickness, a drive voltage of 5.5 V is required and the light-emitting efficiency is 4.90 Cd/A.

In one embodiment, when the plasma surface treatment process is performed under Condition B (the pixel separation layer 170 is etched by a thickness of 100-1000 Å from the deposition thickness), any particles or remnants of organic material used as the pixel separation layer have been removed. This removal improves the surface characteristics of the anode electrode and increases the light-emitting efficiency of red color

Table 2 shows a relation between brightness and light-emitting efficiency according to surface treatment process conditions of red color. In Table 2, the Process Condition is the condition under which the surface treatment process is performed. Condition A indicates that the pixel separation layer is etched by a thickness less than 100 Å. Condition B indicates that the pixel separation layer is etched by a thickness of 100-1000 Å. In Condition B, the surface treatment process may be performed specifically when the pixel separation layer is etched by a thickness of 800 Å.

TABLE 2

| | Drive | | | Color Coordinates | |
|---|---|---|---|---|---|
| Process | Voltage | Brightness | Efficiency | X | Y |
| Condition | (V) | (Cd/m²⁾ | (Cd/A) | Coordinate | Coordinate |
| Condition | 5.5 | 472 | 4.22 | 0.681 | 0.317 |
| A | | | | | |
| Condition | 5.5 | 765 | 4.90 | 0.680 | 0.319 |
| B | | | | | |

In Table 2, when the pixel separation layer 170 is etched by a thickness less than 100 Å from the deposition thickness, the brightness is 472 Cd/m² and the light-emitting efficiency is 4.22 Cd/A at the drive voltage of 5.5 V. In contrast, at the same drive voltage when the pixel separation layer 170 is etched by a thickness of 100-1000 Å from the deposition thickness, the brightness is 765 Cd/m² and the light-emitting efficiency is 4.90 Cd/A.

In one embodiment of the present invention, when the plasma surface treatment process is performed under Condition B (the pixel separation layer 170 is etched by a thickness of 100-1000 Å from the deposition thickness), particles or remnants of the organic material used as the pixel separation layer are removed. This removal improves the surface characteristics of the anode electrode and increases the brightness and the light-emitting efficiency of red color at the same drive voltage.

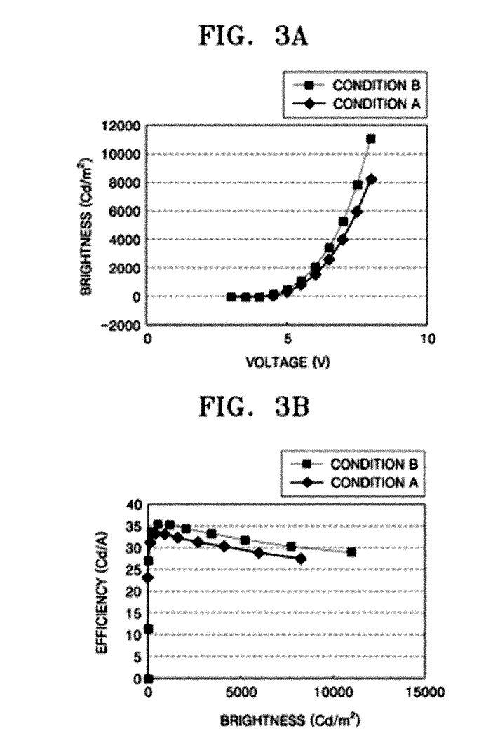

FIG. 3A illustrates a relationship between drive voltage and brightness according to different surface treatment process conditions for red color. In FIG. 3A, the case of performing the plasma surface treatment process under Condition A (that the pixel separation layer is etched by a thickness less than 100 Å) is compared with the case of performing the plasma surface treatment process under Condition B (that the pixel separation layer is etched by a thickness of 100-1000 Å). When the surface treatment process performed under Condition B is compared to the surface treatment process performed under Condition A at the same drive voltage, superior brightness characteristics of red color are observed.

FIG. 3B illustrates a relationship between light-emitting efficiency and brightness according to different surface treatment process conditions for red color. Condition A (that the pixel separation layer is etched by a thickness less than 100 Å) is compared with Condition B (that the pixel separation layer is etched by a thickness of 100-1000 Å). The surface treatment process performed under Condition B yields a higher light-emitting efficiency of red color than Condition A at the same brightness.

Table 3 shows a relationship between drive voltage and light-emitting efficiency according to different surface treatment process conditions of green color. Process Condition refers to the condition under which the surface treatment process is performed. Condition A indicates that the pixel separation layer is etched by a thickness less than 100 Å and Condition B indicates that the pixel separation layer is etched by a thickness of 100-1000 Å. In Condition B, the surface treatment process may be performed when the pixel separation layer is etched by a thickness of 800 Å.

TABLE 3

| | Drive | | | Color Coordinates | |
|---|---|---|---|---|---|
| Process | Voltage | Brightness | Efficiency | X | Y |
| Condition | (V) | (Cd/m²⁾ | (Cd/A) | Coordinate | Coordinate |
| Condition | 5.4 | 800 | 33.13 | 0.332 | 0.611 |
| A | | | | | |
| Condition | 5.2 | 800 | 35.17 | 0.333 | 0.613 |
| B | | | | | |

To achieve a brightness of 800 Cd/cm2 when the pixel separation layer 170 is etched by a thickness less than 100 Å from the deposition thickness, requires a drive voltage of 5.4 V with a light-emitting efficiency of 33.13 Cd/A. In contrast, to achieve the same brightness when the pixel separation layer 170 is etched by a thickness of 100-1000 Å from the deposition thickness, requires a drive voltage of 5.2 V with a light-emitting efficiency of 35.17 Cd/A.

In another embodiment of the present invention, when the plasma surface treatment process is performed under Condition B (that the pixel separation layer 170 is etched by a thickness of 100-1000 Å from the deposition thickness), particles and remnants of organic material used as the pixel separation layer are removed. This removal improves the surface characteristics of the anode electrode and increases the light-emitting efficiency of the OLED.

Table 4 shows a relationship between brightness and light-emitting efficiency according to different surface treatment process conditions of green color. Process Condition refers to the condition under which the surface treatment process is performed. Condition A indicates that the pixel separation layer is etched by a thickness less than 100 Å. Condition B indicates that the pixel separation layer is etched by a thickness of 100-1000 Å. In Condition B, the surface treatment process may be performed under the condition that the pixel separation layer is etched by a thickness of 800 Å.

TABLE 4

| | Drive | | | Color Coordinates | |
|---|---|---|---|---|---|
| Process | Voltage | Brightness | Efficiency | X | Y |
| Condition | (V) | (Cd/m²⁾ | (Cd/A) | Coordinate | Coordinate |
| Condition | 5.5 | 875.9 | 33.11 | 0.332 | 0.611 |
| A | | | | | |
| Condition | 5.5 | 1132 | 35.10 | 0.333 | 0.613 |
| B | | | | | |

When the pixel separation layer 170 is etched by a thickness less than 100 Å from the deposition thickness at a drive voltage of 5.5 V, the brightness is 875.9 Cd/m² and the light-emitting efficiency is 33.11 Cd/A. In contrast, when the pixel separation layer 170 is etched by a thickness of 100-1000 Å from the deposition thickness, the brightness is 1132 Cd/m² and the light-emitting efficiency is 35.10 Cd/A.

In one embodiment of the present invention, when the plasma surface treatment process is performed under Condition B (that the pixel separation layer 170 is etched by a thickness of 100-1000 Å from the deposition thickness), particles and remnants of organic material used as the pixel separation layer have been removed. This removal improves the surface characteristics of the anode electrode and increases the light-emitting efficiency of green color for an OLED at the same voltage.

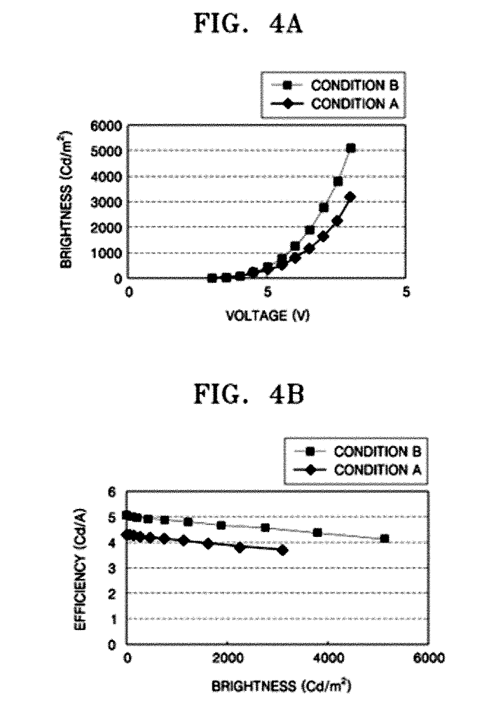

FIG. 4A illustrates a relationship between drive voltage and brightness according to surface treatment process conditions for green color. Condition A, (that the pixel separation layer is etched by a thickness less than 100 Å) is compared with Condition B (that the pixel separation layer is etched by a thickness of 100-1000 Å). As shown in FIG. 4A, at the same drive voltage, superior brightness characteristics of green color are obtained when the surface treatment process is performed under Condition B when compared to the same brightness achieved under Condition A.

FIG. 4B illustrates a relationship between drive voltage and brightness according to surface treatment process conditions for green color. The case of performing the plasma surface treatment process under Condition A (that the pixel separation layer is etched by a thickness less than 100 Å) is compared with the case of performing the plasma surface treatment process under Condition B (that the pixel separation layer is etched by a thickness of 100-1000 Å). As illustrated, when the surface treatment process is performed under Condition B, a higher light-emitting efficiency of green color at the same brightness is obtained.

As illustrated in Tables 1 through 4, color coordinates of red color and green color are nearly constant regardless of the surface treatment process.

Table 5 shows work functions according to different surface treatment process conditions. The Process Condition refers to the condition under which the surface treatment process is performed. Condition A indicates that the pixel separation layer is etched by a thickness less than 100 Å. Condition B indicates that the pixel separation layer is etched by a thickness of 100-1000 Å. In Condition B, the surface treatment process may be performed by etching the pixel separation layer by a thickness of 200-800 Å. Condition C indicates that the surface treatment process is performed by etching the pixel separation layer by a thickness greater than 1000 Å.

TABLE 5

| | | | |
|---|---|---|---|
| Process Condition | Condition A | Condition B | Condition C |
| Work Function | 5.30 eV | 5.48 eV | 5.27 eV |

Table 5 compares work functions when surface treatment processes for removing particles and remnants of organic material used as the pixel separation layer under Conditions A, B and C. Under Condition A, the pixel separation layer is etched by a thickness less than 100 Å. Under Condition B, the pixel separation layer is etched by a thickness of 100-1000 Å. Under Condition C, the pixel separation layer is etched by a thickness greater than 1000 Å.

As illustrated in Table 5, the work function is higher when the pixel separation layer is etched by a thickness of 100-1000 Å than when the pixel separation layer is etched by a thickness less than 100 Å during the surface treatment process. The work function also decreases when the pixel separation layer is etched by a thickness greater than 1000 Å.

Table 6 compares defect ratios according to different surface treatment process conditions. The Process Condition refers to the condition under which the surface treatment process is performed. Condition A indicates that the surface treatment process etched the pixel separation layer by a thickness less than 100 Å. Condition B indicates that the surface treatment process etched the pixel separation layer by a thickness of 100-1000 Å. Condition C indicates that the surface treatment process is performed under by etching the pixel separation layer by a thickness greater than 1000 Å. Under Condition B, the surface treatment process may be performed by etching the pixel separation layer by a thickness of 200-800 Å. Here, the test detecting the number of defects was performed using a 2.2 inch-device mother glass (370 ( 400 mm).

TABLE 6

| Process Condition | Condition A | CONDITION B | Condition C |
|---|---|---|---|
| Number of Defects | <10 | <10 | >50 |

Table 6 further compares the number of defects generated when surface treatment processes for removing the remnants of an organic material used as the pixel separation layer and particles are performed under Conditions A, B and C. In particular, under Condition A, the pixel separation layer is etched by a thickness less than 100 Å. Under Condition B, the pixel separation layer is etched by a thickness of 100-1000 Å. Under Condition C, the pixel separation layer is etched by a thickness greater than 1000 Å.

The number of defects generated during the surface treatment process, both when the pixel separation layer is etched by a thickness less than 100 Å and when the pixel separation layer is etched by a thickness of 100-1000 Å, is less than 10 (< 10). When the pixel separation layer is etched by a thickness greater than 1000 Å, however, the number of defects is greater than 50 (> 50), and thus significantly higher than in the other two cases.

Referring to Tables 1 through 6 and FIGS. 3A, 3B, 4A and 4B, when the surface treatment process is performed under the condition that the pixel separation layer is etched by a thickness of 100-1000 Å from the deposition thickness (preferably, 200 Å through 800 Å), the surface characteristics of the anode electrode are improved, which maximizes both the brightness and the light-emitting efficiency. Further, the work function of the anode electrode is maximized while the defect ratio is minimized.

Although a polysilicon thin film transistor including a polycrystalline silicon layer as the semiconductor layer 110 is an exemplary illustration of a thin film transistor for driving an OLED, the present invention is not limited thereto. Other transistors for use in the present invention may include an amorphous silicon thin film transistor including a semiconductor layer composed of amorphous silicon or an organic thin film transistor including a semiconductor layer composed of an organic semiconductor material, such as pentacene, tetracene, anthracene, naphthalene, alpha-6-thiophene, and/or perylene.

In one embodiment of the present invention, an OLED display is structured such that a thin film transistor is formed on a substrate and a protecting layer is formed on the substrate. The thin film transistor and a pixel electrode are connected through a hole in the protecting layer. Further, a surface treatment process may be performed in such a manner that a pixel separation layer is formed with an opening exposing a portion of the pixel electrode and the pixel separation layer is etched with a predetermined thickness. One embodiment also comprises performing a surface treatment process in an OLED display wherein the OLED display has various sectional structures in such a manner that a pixel separation layer is formed with an opening exposing a portion of a pixel electrode and the pixel separation layer is etched with a predetermined thickness.

In another embodiment of the present invention, a pixel separation layer is formed to expose a portion of a pixel electrode and then, a pre-treatment process is performed. Another embodiment of the present invention comprises a method of fabricating an OLED display in which an opening exposing a portion of a pixel electrode is formed in a planarized layer composed of an organic insulating layer or a protecting layer composed of an organic insulating layer.

In another embodiment of the present invention, an OLED display comprises a front side light-emitting structure, in which a pixel separation layer is formed with an opening exposing a portion of a pixel electrode and then, a pre-treatment process is performed before an organic layer is deposited. An OLED display may also have a back side light-emitting structure or an OLED display comprising a both-sided light-emitting structure. In the both-sided light emitting structure, an insulating layer comprising an opening exposing a portion of a pixel electrode is formed of an organic insulating layer.

As described above, a surface treatment process may etch the pixel separation layer with a predetermined thickness. The pixel separation layer may comprise an opening that exposes a portion of a pixel electrode according to one method of fabricating an OLED display of an embodiment of the present invention. The surface treatment process removes particles or organic remnants due to the formation of the pixel separation layer. This removal improves the characteristics of an organic layer deposited during a subsequent process and lengthens the lifetime of the OLED.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is Claimed is:

1. A method of manufacturing a flat panel display electrode comprising:
forming an electrode material on a substrate;
forming an electrode pattern;
forming an insulating layer having a deposition thickness on the substrate;
etching the insulating layer to expose a portion of the electrode pattern; and
performing a surface treatment process wherein the insulating layer is etched by a predetermined thickness from the deposition thickness.

2. The method according to Claim 1, wherein the surface treatment process is a plasma treatment process using at least one of Ar, O2 and N2 gas.

3. The method according to Claim 1, wherein the surface treatment process is performed by etching the insulating layer by a thickness of about 100-1000 Å from the deposition thickness.

4. The method according to Claim 3, wherein the surface treatment process is performed by etching the insulating layer by a thickness of about 200-800 Å from the deposition thickness.

5. The method according to Claim 3, wherein the surface treatment process is performed using at least one gas of O2, Ar and N2 gas at a flow rate of about 10-600 sccm, a treatment pressure of about 5-700 mTorr and an RF power of about 50- 600 W.

6. The method according to Claim 1, wherein the electrode pattern is a transparent conductive layer including indium-tin-oxide (ITO) and wherein the insulating layer is an organic insulating layer.

7. The method according to Claim 6, wherein the insulating layer includes a planarized layer or a pixel separation layer.

8. The method according to Claim 7, wherein the insulating layer is etched using a photolithography process.

9. A method of manufacturing an organic light emitting diode (OLED) display comprising:
forming a lower electrode on a substrate;
forming an insulating layer having an opening on the lower electrode and having a deposition thickness;
performing a surface treatment process wherein the insulating layer is etched by a predetermined thickness from the deposition thickness;
depositing an organic layer on the lower electrode inside the opening; and
forming an upper electrode on the organic layer.

10. The method according to Claim 9, wherein the surface treatment process is a plasma treatment process using at least one of Ar, O2 and N2 gas.

11. The method according to Claim 9, wherein the surface treatment process is performed by etching the insulating layer by a thickness of about 100-1000 Å from the deposition thickness.

12. The method according to Claim 11, wherein the surface treatment process is performed by etching the insulating layer by a thickness of about 200-800 Å from the deposition thickness.

13. The method according to Claim 12, wherein the surface treatment process is performed using at least one gas of O2, Ar and N2 gas at a flow rate of about 10-600 sccm, a treatment pressure of about 5-700 mTorr and an RF power of about 50-600W.

14. The method according to Claim 9, wherein the lower electrode is a transparent conductive layer including an indium-tin-oxide (ITO) layer and the insulating layer is an organic insulating layer.

15. The method according to Claim 14, wherein the insulating layer includes a planarized layer or a pixel separation layer.

16. The method according to Claim 15, wherein forming an insulating layer further comprises depositing an organic insulating layer and patterning the organic insulating layer using a photolithography process to form the opening.

17. An OLED display fabricated according to the fabrication method of Claim 9.

18. The OLED display according to Claim 17, further comprising a thin film transistor including a semiconductor layer, a gate and source/drain electrodes formed on the substrate, one of the source/drain electrodes being connected to the lower electrode.

19. An electrode of an organic light emitting diode (OLED) OLED formed by a process comprising:
(1) forming an electrode material on a substrate;
(2) forming an electrode pattern with the electrode material;
(3) forming an insulating layer having a deposition thickness on the substrate;
(4) etching the insulating layer to expose a portion of the electrode pattern; and
(5) performing a surface treatment process, wherein the insulating layer is etched by a predetermined thickness from the deposition thickness.

20. A flat panel display electrode comprising:
an electrode material on a substrate, wherein at least a portion of the electrode material is formed into a pattern; and
an insulating layer comprising a deposition thickness on the substrate,
wherein the insulating layer is etched to expose a portion of the electrode pattern, and
wherein a surface treatment process is performed to etch the insulating layer to a predetermined thickness from the deposition thickness.
